(19) United States
(12) Patent Application Publication
(10) Pub. No.: US 2009/0097214 A1
(43) Pub. Date: Apr. 16, 2009

(54) Electronic chip embedded circuit board and method of manufacturing the same

(75) Inventors: Jin-woo Lee, Seongnam-si (KR); Jae-hoon Jang, Seongnam-si (KR)

Correspondence Address: DRINKER BIDDLE & REATH LLP;ATTN: PATENT DOCKET DEPT., 191 N. WACKER DRIVE, SUITE 3700, CHICAGO, IL, 60606, US

(73) Assignee: Samsung Techwin Co., Ltd, Changwon-city (KR)

(21) Appl. No.: 12/152,442

(22) Filed: May 14, 2008

(30) Foreign Application Priority Data
Oct. 15, 2007 (KR) 10-2007-0103706

(51) Int. Cl. H05K 5/00; H05K 3/02

(52) U.S. Cl. 361/752; 29/847

(57) ABSTRACT

Provided is a method of manufacturing a device-embedded circuit board. The method includes: preparing a first substrate with a first pattern portion comprising a conductive material; coupling, for example, an electronic chip to the first substrate; preparing a second substrate with a first through hole corresponding to a part of the first pattern portion, a housing portion for housing the electronic chip, and a first connection portion comprising a conductive material formed in the first through hole; preparing a third substrate with a second through hole corresponding to the first through hole and a second connection portion comprising a conductive material formed in the second through hole; aligning and coupling the first, second and third substrates so that the first pattern portion, the first connection portion and the second connection portion are electrically connected.

### CROSS-REFERENCE TO RELATED PATENT APPLICATION

This application claims the benefit of Korean Patent Application No. 10-2007-0103706, filed on Oct. 15, 2007, in the Korean Intellectual Property Office, the disclosure of which is incorporated herein in its entirety by reference.

### BACKGROUND OF THE INVENTION

1. Field of the Invention

The present invention relates to an electronic chip embedded circuit board and a method of manufacturing the same. More particularly, the present invention relates to an electronic chip embedded circuit board including fine pitch circuit patterns, and a method of manufacturing the same by connecting substrate layers with conductive adhesives.

2. Description of the Related Art

Recently, the size of components constituting an electronic device has been considerably reduced. Furthermore, the number of components in an electronic device has been increased due to consumers' need for multi-functional products. As a surface area of a circuit board is further reduced, and simultaneously the number of components formed on the circuit board is further increased, the components which used to be mounted on a surface of a circuit board are now often embedded in the circuit board.

Especially, when an active element is embedded in a circuit board, since a distance between a passive element and the active element is reduced, the circuit board can be used in an electronic package requiring good electronic performance. In addition, when an electronic chip is embedded in a circuit board, a small form factor circuit board can be realized, the number of steps required for mounting various components on a circuit board having a small surface-area is reduced, and a space for arranging the components is increased. Thus, the circuit board can be more freely designed.

Generally, when an electronic chip embedded circuit board is manufactured, a build-up technique in which a plurality of circuit boards are stacked to be a multi-layered circuit board is used. When the circuit boards are stacked, resin coated copper (RCC), which is a material for stacking, is widely used.

However, when an electronic chip embedded in a circuit board is manufactured using RCC, an interconnection operation, in which circuits of different layers are electrically connected, is required and a terminal of an electronic chip embedded in the circuit board is electrically connected to the circuits, in addition to forming a stack structure by thermal pressing RCC. The interconnection operation of electrically connecting inter-layers is difficult and includes various complicated operations.

Such various complicated operations include: forming a mask having a shape corresponding to a via hole; forming a pattern by using photolithography with the mask; processing the via hole by using a drill operation; desmear-processing the processed via hole; and plating the via hole. Since these complicated operations are included in the conventional method, and many etching operations are required for forming patterns, the manufacturing costs of the conventional method are increased.

Via holes of built-up chip-embedded boards are typically processed using a drill operation in order to expose the terminal of the electronic chip embedded in the circuit board to the outside. However, it is difficult to perform the drill operation without damaging the electronic chip.

According to the conventional method of manufacturing a circuit board by using RCC, it is difficult to manufacture a circuit board including circuit patterns having a fine pitch since the RCC has a B-stage prepreg. Due to the recent tendency to make small-sized electronic devices, the interval and height of a circuit pattern are preferred to have a detail level of 20/20 μm or less. However, a circuit pattern having such a fine pitch cannot be realized by the technology using RCC.

In addition, when a method of manufacturing a circuit board using RCC is used to make a flexible circuit board, the flexibility of the circuit board can deteriorate.

### SUMMARY OF THE INVENTION

According to an aspect of the present invention, there is provided a method of manufacturing an electronic chip embedded circuit board, the method including: preparing a first substrate formed of an insulating material, wherein a first pattern portion comprising a conductive material is formed on the first substrate; coupling an electronic chip to the first substrate; preparing a second substrate formed of an insulating material, wherein first through holes and a housing portion are formed in the second substrate, the first through holes corresponding to a part of the first pattern portion, and the housing portion being configured to protect and support the electronic chip, and a first connection portion formed of a conductive material is formed in the first through holes; preparing a third substrate formed of an insulating material, wherein second through holes corresponding to the first through holes are formed in the third substrate, and a second connection portion comprising a conductive material is formed in the second through holes; coupling the first, second and third substrates, wherein the first, second and third substrates are disposed so as to align the first pattern portion, the first connection portion and the second connection portion, and conductive adhesives are interposed between the first substrate and the second substrate, and between the second substrate and the third substrate; and curing or hardening the conductive adhesives.

According to another aspect of the present invention, there is provided an electronic chip embedded circuit board. One embodiment of the circuit board includes: a first substrate on which a first pattern portion is formed on a surface of the first substrate; an electronic chip that is attached to the side surface of the first substrate and that is electrically connected to the first pattern portion; a second substrate comprising a housing portion (e.g., an aperture) configured to protect and support the electronic chip, first through holes corresponding to a part of the first pattern portion, and a first connection portion formed of a conductive material and formed in the first through holes, wherein the second substrate is formed of an insulating material, and is coupled to the first substrate by interposing therebetween conductive adhesives; and a third substrate comprising second through holes corresponding to the first through holes, a second connection portion formed of a conductive material and formed in the second through holes, and a second pattern portion formed on the second connection portion so as to be electrically connected to the second connection portion, wherein the third substrate is coupled to the second substrate by interposing therebetween conductive adhesives, and is formed of an insulating material.

The conductive adhesives may include an anisotropic conductive material.

The conductive adhesives may be anisotropic conductive films (ACF).

The preparing of the third substrate may further include forming a second pattern portion, which comprises a conductive material and is electrically connected to the second connection portion, on the third substrate.

The first, second, and third substrates may be flexible.

In the preparing of the first, second and third substrates, the first, second and third substrates may be prepared to be wound around a roll, and while the first, second, and third substrates may be released from the roll, the preparing of the first substrate through the hardening may be performed.

The curing or hardening step/operation may include applying heat and pressure to the first, second, and third substrates.

The curing or hardening step/operation may include applying sonic waves (e.g., ultrasonic) and pressure to the first, second, and third substrates.

The forming of the first pattern portion may include: coating resist on the conductive material; performing exposing and developing with respect to a resulting structure; and removing a part of the conductive material by using etching.

In some embodiments the housing portion may be formed as an aperture through the second substrate. In other embodiments, the housing portion may be a depression, cavity or recess in a surface of the second substrate.

According to another aspect of the present invention, there is provided a method of manufacturing an electronic chip embedded circuit board, the method including: preparing a first substrate formed of an insulating material, wherein a first pattern portion comprising a conductive material is formed on the first substrate; coupling an electronic chip to the first substrate; preparing a second substrate formed of an insulating material, wherein through holes corresponding to a part of the first pattern portion, and a housing portion housing the electronic chip are formed in the second substrate, and a connection portion comprising a conductive material is formed in the through holes; coupling the first and second substrates, wherein the first and second substrates are disposed so as to align the first pattern portion and the through holes, and conductive adhesives are interposed between the first substrate and the second substrate; and hardening the conductive adhesives.

The preparing of the second substrate may further include forming a second pattern portion, which is formed of a conductive material and is electrically connected to the through holes, on the second substrate.

The housing portion may be concavely formed so that a surface of the second substrate, which faces the electronic chip, generally corresponds to the shape of the electronic chip.

### BRIEF DESCRIPTION OF THE DRAWINGS

The above and other features of the present invention will become more apparent by describing in detail exemplary embodiments thereof with reference to the attached drawings in which:

FIG. 1 is a cross-sectional view of a first substrate for explaining an initial operation of preparing a first substrate in a method of manufacturing a circuit board, according to an embodiment of the present invention;

FIG. 2 is a cross-sectional view for explaining an operation of forming a first pattern portion on the first substrate illustrated in FIG. 1, according to an embodiment of the present invention;

FIG. 3 is a cross-sectional view for explaining an operating coupling an electronic chip to the first substrate illustrated in FIG. 2, according to an embodiment of the present invention;

FIG. 4 is a cross-sectional view of a second substrate for explaining an initial operation of preparing a second substrate, in a method of manufacturing a circuit board, according to an embodiment of the present invention;

FIG. 5 is a cross-sectional view for explaining an operation of forming first through holes in the second substrate illustrated in FIG. 4, according to an embodiment of the present invention;

FIG. 6 is a cross-sectional view for explaining an operation of forming a first connection portion comprising a conductive material in the first through holes of the second substrate illustrated in FIG. 5, according to an embodiment of the present invention;

FIG. 7 is a cross-sectional view for explaining an operation of removing a passivation layer from the second substrate illustrated in FIG. 6, according to an embodiment of the present invention;

FIG. 8 is a cross-sectional view of a third substrate for explaining an initial operation of preparing a third substrate in a method of manufacturing a circuit board, according to an embodiment of the present invention;

FIG. 9 is a cross-sectional view for explaining an operation of forming second through holes in the third substrate illustrated in FIG. 8, according to an embodiment of the present invention;

FIG. 10 is a cross-sectional view for explaining an operation of forming a second connection portion comprising a conductive material in the second through holes of the third substrate, according to an embodiment of the present invention;

FIG. 11 is a cross-sectional view for explaining an operation of forming the second pattern portion on the third substrate illustrated in FIG. 10, according to an embodiment of the present invention;

FIG. 12 is a cross-sectional view for explaining an operation of coupling the first, second and third substrates of FIGS. 3, 7 and 11 respectively, according to an embodiment of the present invention;

FIG. 13 is a cross-sectional view for explaining a completed circuit board, according to an embodiment of the present invention;

FIG. 14 is a perspective view of the substrates of FIG. 12, according to an embodiment of the present invention;

FIG. 15 is a flow chart of an example method of manufacturing the multi-layer, built-up chip-embedded circuit board of FIG. 13, according to an embodiment of the present invention;

FIG. 16 is a cross-sectional view for explaining an operation of preparing a second substrate, in another method of manufacturing a circuit board, according to another embodiment of the present invention;

FIG. 17 is a cross-sectional view for explaining an operation of forming through holes in the second substrate illustrated in FIG. 16, according to another embodiment of the present invention;

FIG. 18 is a cross-sectional view for explaining an operation of forming a connection portion comprising a conductive material in the through holes of the second substrate illustrated in FIG. 17, according to another embodiment of the present invention;

FIG. 19 is a cross-sectional view for explaining an operation of forming a second pattern portion on the second substrate illustrated in FIG. 18, according to another embodiment of the present invention;

FIG. 20 is a cross-sectional view for explaining an operation of coupling the first substrate to the second substrate illustrated in FIGS. 3 and 19 respectively, according to another embodiment of the present invention; and

FIG. 21 is a cross-sectional view for explaining a completed circuit board, according to another embodiment of the present invention.

### DETAILED DESCRIPTION OF THE INVENTION

Hereinafter, the present invention will be described in detail by explaining various example embodiments of the invention with reference to the attached drawings.

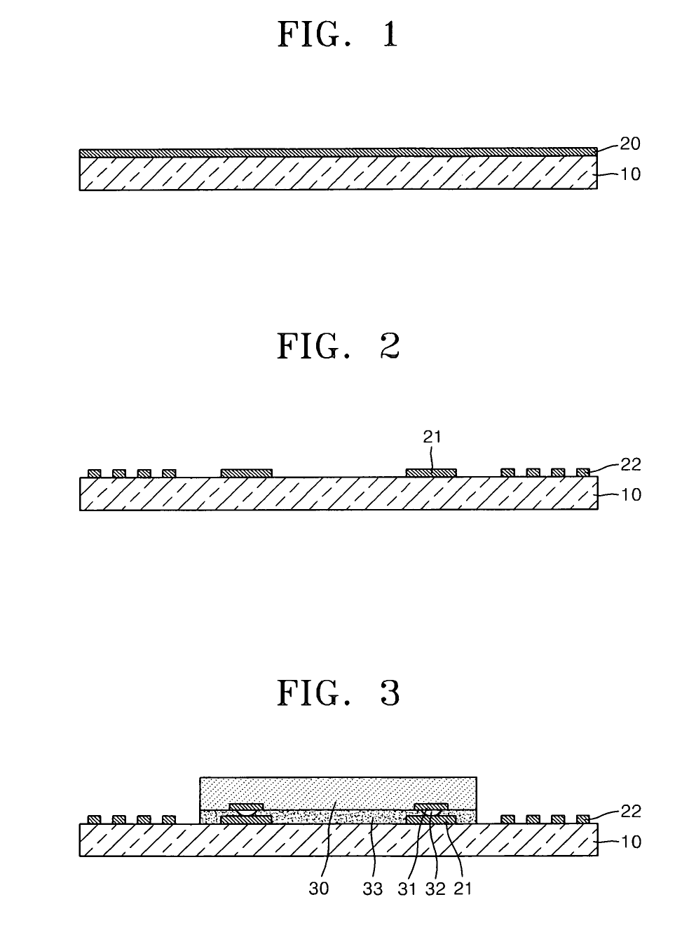

FIG. 1 is a cross-sectional view for explaining an operation of preparing a first substrate 10 in a method of manufacturing a circuit board, according to an embodiment of the present invention. FIG. 2 is a cross-sectional view for explaining an operation of forming a first pattern portion 22 on the first substrate 10 illustrated in FIG. 1, according to an embodiment of the present invention.

The first substrate 10 is formed of an insulating material. When the circuit board is manufactured as a flexible circuit board, the first substrate 10 may include a flexible material, such as a polyimide resin.

A conductive layer 20 is formed on the first substrate 10. The conductive layer 20 is an element from which a circuit pattern (or patterns) is formed for transmitting electric signals on the circuit board, and thus the conductive layer 20 comprises a conductive material. The conductive layer 20 may include copper.

In an operation of preparing the first substrate 10, the first pattern portion 22 comprising a conductive material is formed on the first substrate 10, which is formed of an insulating material. The first pattern portion 22 functions as a circuit that transmits electric signals on the first substrate 10 of the circuit board.

The first pattern portion 22 may be formed using an operation of removing portions of the conductive layer 20 by etching the conductive layer 20. That is, the first pattern portion 22 may be formed on the first substrate 10 by using a method in which: a photosensitive resist layer is formed on the conductive layer 20; a mask is disposed on the resulting structure to be exposed; the resulting structure is developed; and then the portions of the conductive layer 20 are removed using an etching solution.

Although the first pattern portion 22 may be formed on the first substrate 10 by using photolithography as described above, the present invention is not limited thereto. The first pattern portion 22 may be formed using various subtractive or additive methods known in the art including plating, printing, or the like.

FIG. 3 is a cross-sectional view for explaining an operation of coupling an electronic chip to the first substrate 10 illustrated in FIG. 2, according to an embodiment of the present invention.

In the present embodiment, the electronic chip coupled to the first substrate 10 is a semiconductor chip 30. However, the present invention is not limited to the electronic chip or coupling an electronic chip to the first substrate 10. Indeed, various active or passive elements having various shapes, sizes, etc. may be used in addition or as an alternative to the electronic chip.

Various methods can be used for coupling the semiconductor chip 30 to the first substrate 10. However, a wafer level package is used in FIG. 3 in which the semiconductor chip 30 is directly mounted on the first pattern portion 22 of the first substrate 10, rather than the chip 30 being packaged.

In particular, a plurality of non-solder bumps 32 are respectively formed on a plurality of connection terminals 31 of the semiconductor chip 30 included in a wafer (not shown), and then an anisotropic conductive film (ACF) 33 is laminated on the entire wafer so as to cover the non-solder bumps 32. Then, the wafer is cut to correspond to each semiconductor chip 30, and then flip chip mounting is performed on the first substrate 10, particularly on the first pattern portion 22.

Thus, the non-solder bumps 32, which are respectively attached to the connection terminals 31 of the semiconductor chip 30, are electrically connected to the respective terminals 21 of the first substrate 10 due to the ACF 33, and the semiconductor chip 30 is mounted on the first substrate 10.

When the semiconductor chip 30 is mounted on the first substrate 10 as illustrated in FIG. 3, a second substrate and a third substrate, which will be later described, are coupled to each other and to the first substrate 10 to cover the semiconductor chip 30, in operations which will be described hereinafter. Thus, the semiconductor chip 30 can be embedded in the completed circuit board.

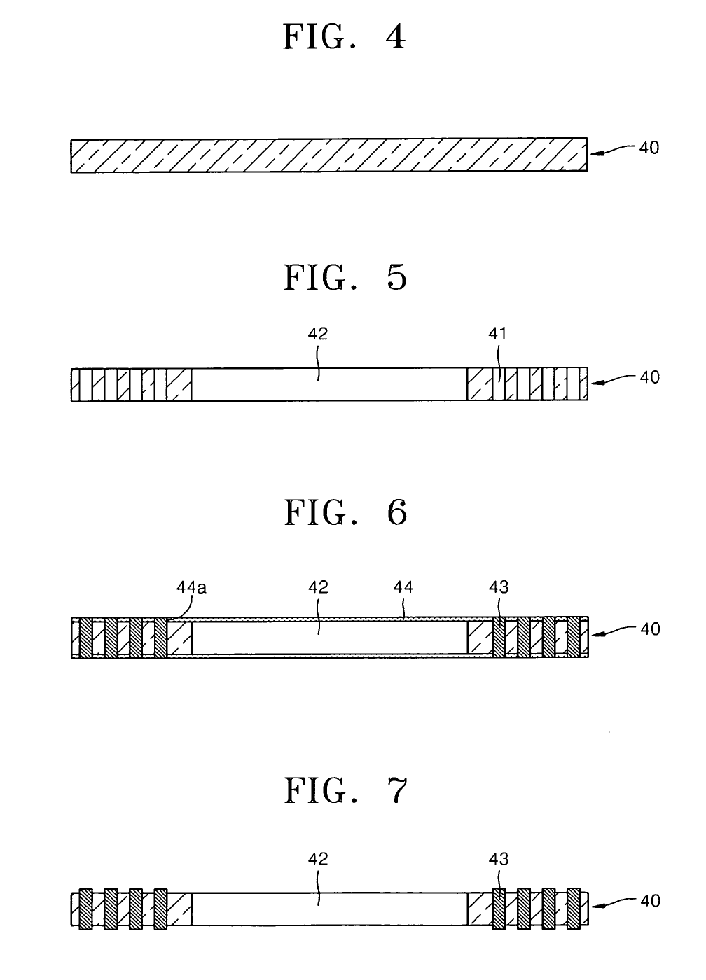

FIG. 4 is a cross-sectional view for explaining an operation of preparing a second substrate 40 in a method of manufacturing a circuit board, according to an embodiment of the present invention. FIG. 5 is a cross-sectional view for explaining an operation of forming first through holes 41 in the second substrate 40 illustrated in FIG. 4, according to an embodiment of the present invention. FIG. 6 is a cross-sectional view for explaining an operation of forming a first connection portion 43 comprising a conductive material in the first through holes 41 of the second substrate 40 illustrated in FIG. 5, according to an embodiment of the present invention. FIG. 7 is a cross-sectional view for explaining an operation of removing a passivation layer 44 from the second substrate 40 illustrated in FIG. 6, according to an embodiment of the present invention.

The second substrate 40 is formed of an insulating material. The second substrate 40 is configured to be disposed between the first substrate 10 and the third substrate to be described later which covers the semiconductor chip 30, and thus the second substrate 40 can function as an intermediate layer insulating the first substrate 10 from the third substrate. When the circuit board is a flexible circuit board, the second substrate 40 may also include a flexible material, such as a polyimide resin, that is similar or different than a material of the first substrate 10.

Preparing the second substrate 40 includes: forming the first through holes 41 and a housing portion 42 in the second substrate 40; and forming the first connection portion 43 comprising a conductive material in the first through holes 41.

The first through holes 41 function as via holes that electrically connect the first pattern portion 22 to a pattern or patterns of the third substrate, which will be later described. Thus, the first through holes 41 are formed on a portion of the second substrate 40 which corresponds to a part of the first pattern portion 22 of the first substrate 10. That is, the first through holes 41 are configured to be aligned with the first pattern portion 22.

The first connection portion 43 comprising a conductive material may be formed in the first through holes 41 by using electroless plating. The passivation layer 44 (e.g., a mask), in which openings 44a corresponding to the first through holes 41 are formed, is attached onto or otherwise disposed on the second substrate 40 illustrated in FIG. 5, and then the electroless plating is performed with respect to the resulting structure. Thus, the first connection portion 43 is formed in the first through holes 41 as illustrated in FIG. 7. Since the first connection portion 43 should be conductive, the first connection portion 43 may comprise a conductive material such as copper (Cu).

The first connection portion 43 is formed using electroless plating, but the present invention is not limited thereto. The first connection portion 43 may be formed using various additive and subtractive methods known in the art such as deposition, and a method of filling the first through holes 41 with conductive powder and hardening the conductive powder.

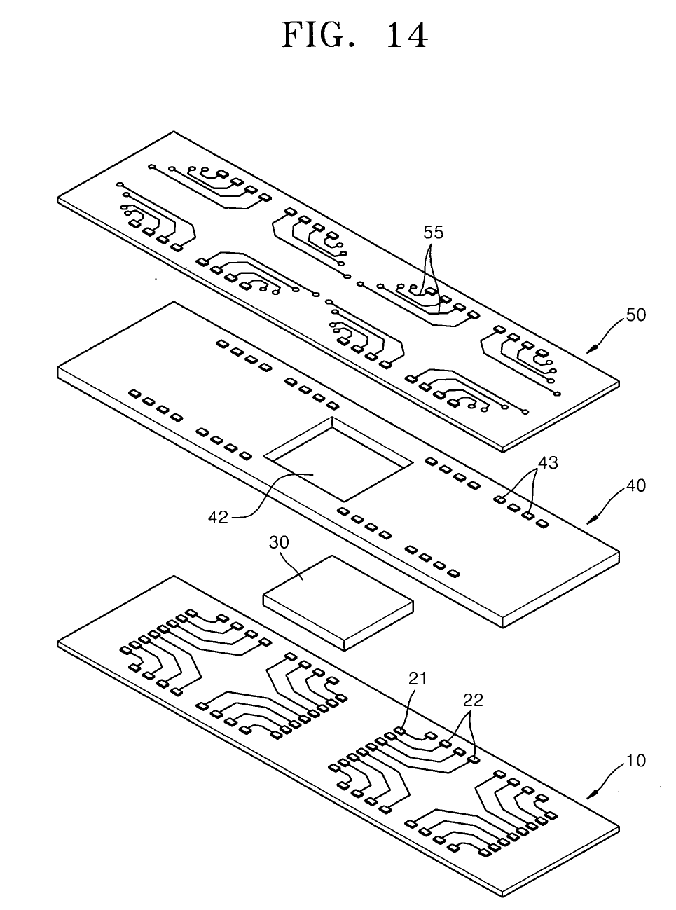

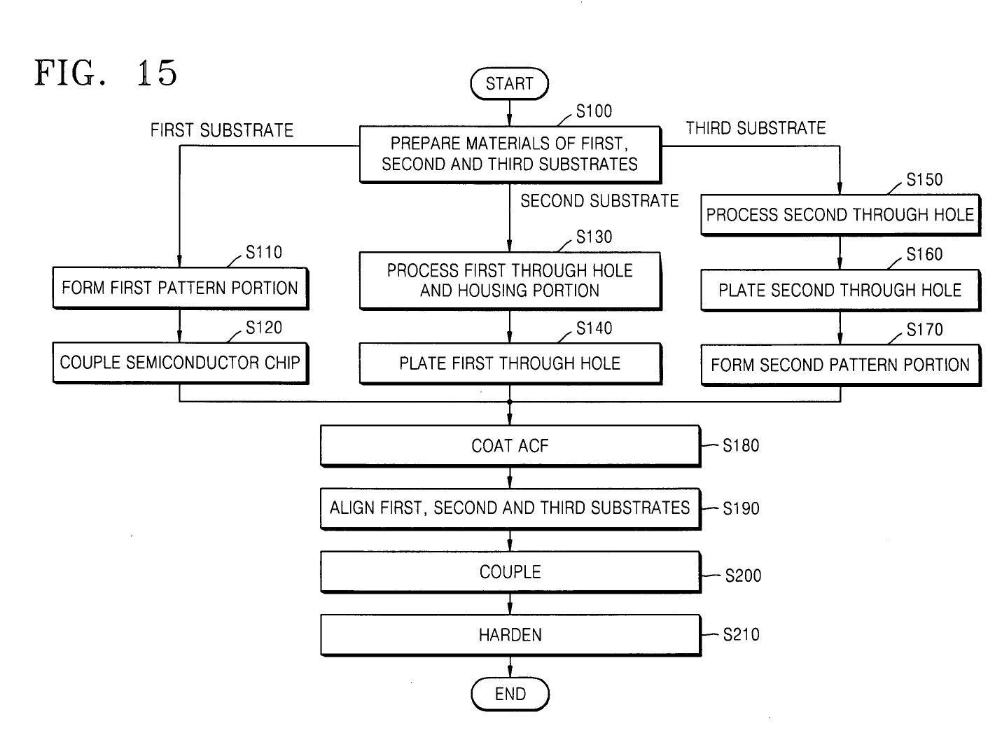

As can be appreciated from FIG. 14, the housing portion 42 may be an aperture formed in a shape generally corresponding to a perimeter of the semiconductor chip 30. Thus, when the second substrate 40 is coupled to the first substrate 10, the second substrate 40 surrounds and supports the semiconductor chip 30. Thus the second substrate 40 can insulate the semiconductor chip 30 from other elements of the circuit board. The second substrate 40 may have a thickness that is the approximately same as the thickness (or height) of the semiconductor chip 30. However, in other embodiments, the second substrate may be thicker than the thickness of the chip 30.

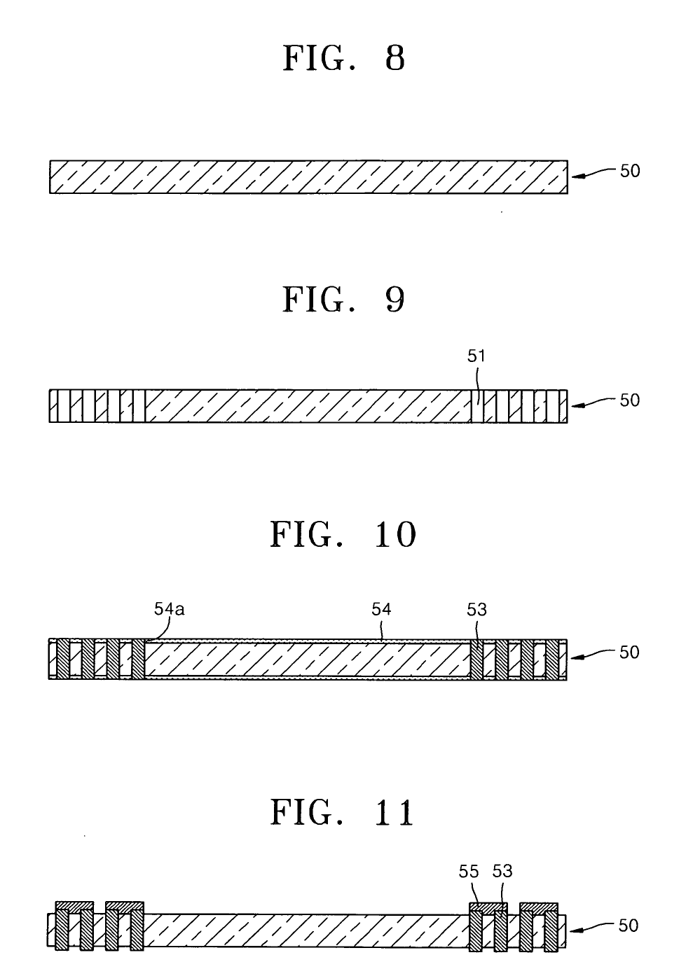

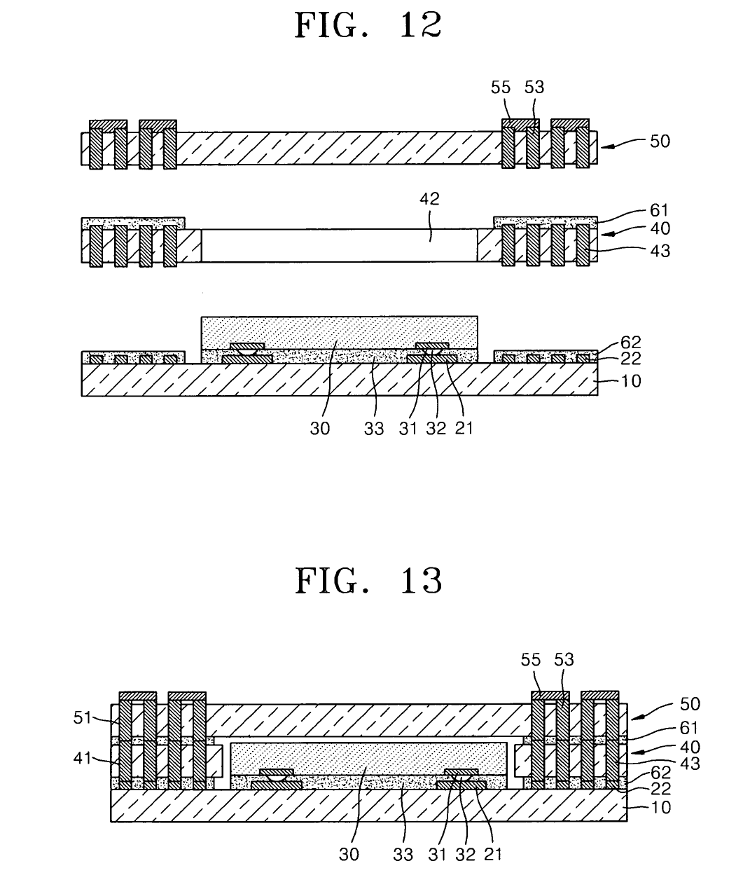

FIG. 8 is a cross-sectional view for explaining an operation of preparing a third substrate 50 in a method of manufacturing a circuit board, according to an embodiment of the present invention. FIG. 9 is a cross-sectional view for explaining an operation of forming second through holes 51 in the third substrate 50 illustrated in FIG. 8, according to an embodiment of the present invention. FIG. 10 is a cross-sectional view of an operation of forming a second connection portion 53 comprising a conductive material in the second through holes 51 of the third substrate 50, according to an embodiment of the present invention. FIG. 11 is a cross-sectional view of an operation of forming the second pattern portion 55 on the third substrate 50 illustrated in FIG. 10, according to an embodiment of the present invention.

The third substrate 50 is formed of an insulating material. The third substrate 50 is configured to cover the semiconductor chip 30 and the second substrate 40. The second pattern portion 55 is formed on the third substrate 50. When the circuit board is a flexible circuit board, the third substrate 50 may include a flexible material such as a polyimide resin.

Preparing the third substrate 50 includes: forming the second through holes 51 in the third substrate 50; and forming the second connection portion 53 comprising a conductive material in the second through holes 51.

The second through holes 51 function as via holes that electrically connect the first connection portion 43 of the second substrate 40 to the second pattern portion 55 formed on the third substrate 50. Thus, the second through holes 51 are formed on a portion of the third substrate 50, which corresponds to the first through holes 41. That is, the second through holes 51 are configured to be generally aligned with the first connection portion 43, which is generally aligned with the first pattern portion 22.

The second connection portion 53 comprising a conductive material is formed in the second through holes 51 by using the electroless plating, which may also be used for forming the first connection portion 43. A passivation layer 54 (e.g., a mask), in which openings 54a corresponding to the second through holes 51 are formed, is attached onto the third substrate 50 illustrated in FIG. 9, and then electroless plating is performed with respect to the resulting structure. Thus, the second connection portion 53 is formed in the second through holes 51, as illustrated in FIG. 10. Since the second connection portion 53 should be conductive, the second connection portion 53 may comprise a conductive material such as copper (Cu).

The second connection portion 53 is formed using the electroless plating, but the present invention is not limited thereto. The second connection portion 53 may be formed using various additive or subtractive methods known in the art such as deposition, and a method of filling the second through holes 51 with conductive powder and hardening the conductive powder.

The preparing of the third substrate 50 further includes: forming the second pattern portion 55 on the third substrate 50. The second pattern portion 55 functions as a circuit that transmits electric signals on the third substrate 50 of the completed circuit board.

The second pattern portion 55 is formed using various methods such as photolithography in which a conductive layer is formed on the third substrate 50, a photosensitive resist layer is formed on the conductive layer to be exposed and developed, and the conductive layer is etched, and a printing method.

Likewise, the operation of forming the second pattern portion 55 on the third substrate 50 may be performed in the operation of preparing the third substrate 50, but the present invention is not limited thereto. That is, the operation of forming the second pattern portion 55 on the third substrate 50 may be performed at a different manufacturing stage such as after the circuit board is completed by coupling together the first substrate 10, the second substrate 40, and the third substrate 50.

As described previously, the forming of the first substrate 10, the forming of the second substrate 40, and the forming of the third substrate 50 may be separately performed, and thus respective substrate-forming operations may be simultaneously performed. Accordingly, in comparison with a conventional manufacturing method in which a circuit board is manufactured by sequentially forming and subsequently stacking various substrates, a manufacturing time of the method of manufacturing the circuit board can be reduced, according to an embodiment of the present invention.

FIG. 12 is a cross-sectional view for explaining an operation of coupling the first, second and third substrates 10, 40 and 50 of FIGS. 3, 7 and 11 respectively, according to an embodiment of the present invention.

After the first, second and third substrates 10, 40 and 50 are prepared, the first, second and third substrates 10, 40 and 50 are coupled to each other, as illustrated in FIG. 12. In the coupling operation, the first substrate 10, the second substrate 40, and the third substrate 50 are disposed so as to align the first pattern portion 22 of the first substrate 10, the first connection portion 43 of the second substrate 40, and the second connection portion 53 of the third substrate 50 with one another. After aligning the substrates, the first, second and third substrates 10, 40 and 50 are coupled to each other using conductive adhesives. The conductive adhesive or adhesives that are used between the first substrate 10 and the second substrate 40, and between the second substrate 40 and the third substrate 50 may include an anisotropic conductive material (i.e., an anisotropic conductive film (ACF)).

The ACF may include a conductive adhesive layer formed by mixing a conductive particle (e.g., a plastic particle including metal coated thereon, or a metal particle) having a corpuscular, spherical or other suitable shape known in the art, adhesives, and additive (e.g., dispersing agent). The ACF is formed in the shape of a thin film.

As shown in FIG. 12, a first ACF 62 is coated on the first pattern portion 22, between the first substrate 10 and the second substrate 40. Thus, after a hardening or curing operation is performed, the first pattern portion 22 and the first connection portion 43 are electrically connected to each other due to the first ACF 62. Also, the first substrate 10 and the second substrate 40 are mechanically fastened, connected, affixed or otherwise coupled to each other.

A second ACF 61 is coated on surfaces of the first connection portion 43 and the second substrate 40, which face the third substrate 50, between the second substrate 40 and the third substrate 50. The second ACF 61 may be the same as or different than the first ACF 62. During the hardening or curing operation, the first connection portion 43 and the second connection portion 53 are electrically connected to each other due to the second ACF 61, and the second substrate 40 and the third substrate 50 are coupled to each other, as well.

After the coupling operation, an operation of hardening or curing the ACFs 61 and 62 may be performed. The hardening or curing operation may be performed using a method in which heat and pressure or heat and sonic waves (e.g., ultrasonic frequency) are applied to the first, second and third substrates 10, 40 and 50. When pressure is applied to the substrates 10, 40, 50 along with heat or sonic waves, the first pattern portion 22 and the first connection portion 43, and the first connection portion 43 and the second connection portion 53 are electrically connected due to the ACFs 61 and 62, respectively. That is, when the ACFs 61, 62 are hardened or cured, a conductive path is established between the chip 30, which is connected to the first pattern portion 22, and the second connection portion 53 so that the chip 30 can communicate with other elements, circuits, systems, etc. external to the present chip-embedded circuit board.

FIG. 13 is a cross-sectional view of a completed circuit board, according to an embodiment of the present invention. FIG. 14 is an exploded perspective view of the circuit board of FIG. 13, according to an embodiment of the present invention.

The circuit board of FIG. 13 includes the first substrate 10 formed of an insulating material, the semiconductor chip 30 that is an electronic chip formed on the first substrate 10, the second substrate 40 formed of an insulating material and coupled to the first substrate 10, and the third substrate 50 formed of an insulating material and coupled to the second substrate 40.

The first pattern portion 22, functioning as a circuit pattern for transmitting signals, is formed on a surface of the first substrate 10 (e.g., the same surface on which the chip 30 is mounted).

The non-solder bumps 32, which are respectively attached to the connection terminals 31 of the semiconductor chip 30, are electrically connected to the terminal 21 constituting a part of the first pattern portion 22 on the first substrate 10. Accordingly, the semiconductor chip 30 is installed on the first substrate 10 so as to be electrically connected to the first pattern portion 22.

The second substrate 40 is formed of an insulating material, and includes a housing portion 42 for housing the semiconductor chip 30, the first through holes 41 corresponding to the first pattern portion 22, and the first connection portion 43 comprising a conductive material formed in the first through holes 41. The second substrate 40 and the first substrate 10 are coupled by interposing therebetween an ACF 62, which is a conductive adhesive. The first connection portion 43 of the second substrate 40 can be electrically connected to the first pattern portion 22 of the first substrate 10 by the ACF 62.

As is best shown in FIG. 14, the housing portion 42 is formed in a shape corresponding to a perimeter of the semiconductor chip 30. Thus, when the second substrate 40 is coupled to the first substrate 10, the second substrate 40 surrounds and supports the semiconductor chip 30, and thus the second substrate 40 can insulate the semiconductor chip 30 from other elements of the semiconductor chip 30.

The third substrate 50 is formed of an insulating material, and includes the second through holes 51 corresponding to the first through holes 41 and the second connection portion 53 comprising a conductive material in the second through holes 51. The third substrate 50 and the second substrate 40 are coupled to each other by interposing therebetween the ACF 61, which is formed of conductive adhesives. The second connection portion 53 of the third substrate 50 can be electrically connected to the first connection portion 43 of the second substrate 40.

The second pattern portion 55 that is electrically connected to the second connection portion 53 may be formed on the third substrate 50. The second pattern portion 55 functions as a circuit pattern transmitting electric signals on the circuit board.

The semiconductor chip 30 is embedded in the completed circuit board by coupling the first, second and third substrates 10, 40, and 50 having the structure described previously. Since the first, second and third substrates 10, 40, and 50 constituting respective layers of the circuit board may be electrically connected by the ACFs 61, 62 and the first and second connection portions 43 and 53, it is unnecessary to drill the semiconductor chip 30 since drilling has been known to damage the semiconductor chip 30 during manufacturing of conventional chip-embedded circuit boards. In addition, when embodiments of the present circuit board are manufactured, expensive and complicated operations, such as an etching operation, are not required.

When the first, second and third substrates 10, 40, and 50 are each formed of a flexible material, such as a polyimide resin, the completed circuit board is a flexible circuit board.

FIG. 15 is a flow chart of an example method of manufacturing the circuit board through operations described with respect to FIGS. 1 through 13, according to an embodiment of the present invention.

Referring to FIG. 15, the illustrated example method of manufacturing the circuit board includes: preparing materials of the first, second, and third substrates (S100); preparing the first substrate (S110 and S120); preparing the second substrate (S130 and S140); preparing the third substrate (S150, S160 and S170); coating an ACF on one or more of the substrates (S180); aligning and coupling the first, second and third substrates (S190 and S200); and hardening or curing the resulting structure (e.g., by applying pressure together with heat or sonic waves to the resulting structure) (S210).

The preparing of the first substrate (S110 and S120), the preparing of the second substrate (S130 and S140), and the preparing of the third substrate (S150, S160 and S170) can be separately performed, and thus respective preparing operations may be simultaneously performed. Accordingly, in comparison with a conventional manufacturing method in which a circuit board is manufactured by sequentially forming and subsequently stacking various substrates, a manufacturing time of the method of manufacturing the circuit board can be reduced, according to an embodiment of the present invention.

The preparing of the first substrate includes: forming a first pattern unit on the first substrate (S110); and coupling or installing a semiconductor chip, which is an electronic chip, to the first substrate (S120).

The preparing of the second substrate includes: processing first through holes and a housing portion in the second substrate (S130); and plating the first through holes (S140).

The plating of the third substrate includes: processing second through holes in the third substrate (S150); plating the second through holes (S170); and forming a second pattern portion, which is electrically connected to the second through holes, on the third substrate (S180).

The first through holes and the second through holes are plated with a conductive material such as copper (Cu), and thus the first through holes and the second through holes can electrically connect the chip to an external element, circuit, system, etc. through the second and third substrates.

When the preparing of the first, second and third substrates is terminated, an ACF is coated on the first substrate and the second substrate (S180), and the first, second and third substrates are aligned (S190), and then the first, second and third substrates are coupled to each other (S200). However, the forgoing operations may be performed in other sequences such as, for example, aligning (S190) and then coating ACF (S180).

In the aligning of the first, second and third substrates, the first pattern portion of the first substrate and the first through holes of the second substrate are aligned, and then the first through holes of the second substrate and the second through holes of the third substrate are aligned. However, the aligning may be performed otherwise, for example by aligning the first and third substrates and then inserting the second substrate therebetween and aligning it with the first and third substrates. Indeed, other aligning operations may be performed, for example by using fiducial marks, etc. The coupling of the first, second and third substrates is an operation in which the first, second and third substrates are mechanically fastened or coupled together.

After the coupling of the first, second, and third substrates is terminated, the hardening or curing operation is performed by applying heat and pressure, or sonic waves and pressure to the resulting multi-layer built-up structure (S210). Thus, the first, second and third substrates can be electrically connected to one another and can be coupled to each other by the ACF.

In a conventional method of manufacturing an electronic chip embedded circuit board, an interconnection operation, in which circuit patterns of different layers are electrically connected, includes various complicated operations such as photolithography, a drill operation, a plating operation, or the like. However, in the method of manufacturing the circuit board according to an embodiment of the present invention, since the circuit board can be manufactured by coupling the first, second, and third substrates (which are previously prepared) using ACF, an additional drill operation or etching operation is not required. Thus, the method can be simplified, and the manufacturing costs of the method can be reduced.

In addition, in the conventional method, a semiconductor chip can be damaged during a drill operation in order to expose a terminal of an electronic chip embedded in a circuit board to the outside. However, according to the present invention, since a semiconductor chip is embedded in a circuit board by using flip chip mounting technique with an ACF, and circuit patterns of layers can be electrically connected to each other by the ACF, danger of damaging the semiconductor chip can be reduced.

In the conventional method in which resin coated copper (RCC) for stacking is mainly used in order to manufacture an electronic chip embedded circuit board, it is very difficult to manufacture a circuit board including a circuit pattern having a fine pitch since the RCC has a B-stage prepreg.

However, in the method of manufacturing a circuit board according to the present invention, since the first, second, and third substrates are coupled to each other by interposing an ACF, and simultaneously, circuit patterns of the first, second and third substrates are electrically connected by the ACF, it is easy to manufacture the circuit board including a circuit pattern having a fine pitch.

In addition, in the conventional method of manufacturing an electronic chip embedded circuit board, since the flexibility of the RCC for stacking used in the conventional method is poor, the RCC is not appropriate for manufacturing a flexible circuit board. However, in the present invention, since the first, second and third substrates comprising a flexible material, such as a polyimide resin, the circuit board having good flexibility can be manufactured.

In the present invention, when the first, second, and the third substrates are each formed of a flexible material in order to manufacture a flexible circuit board, the first, second, and third substrates are prepared to be wound around a roll, the first, second, and third substrates are released from the roll, and all operations for manufacturing the circuit board can be simultaneously performed.

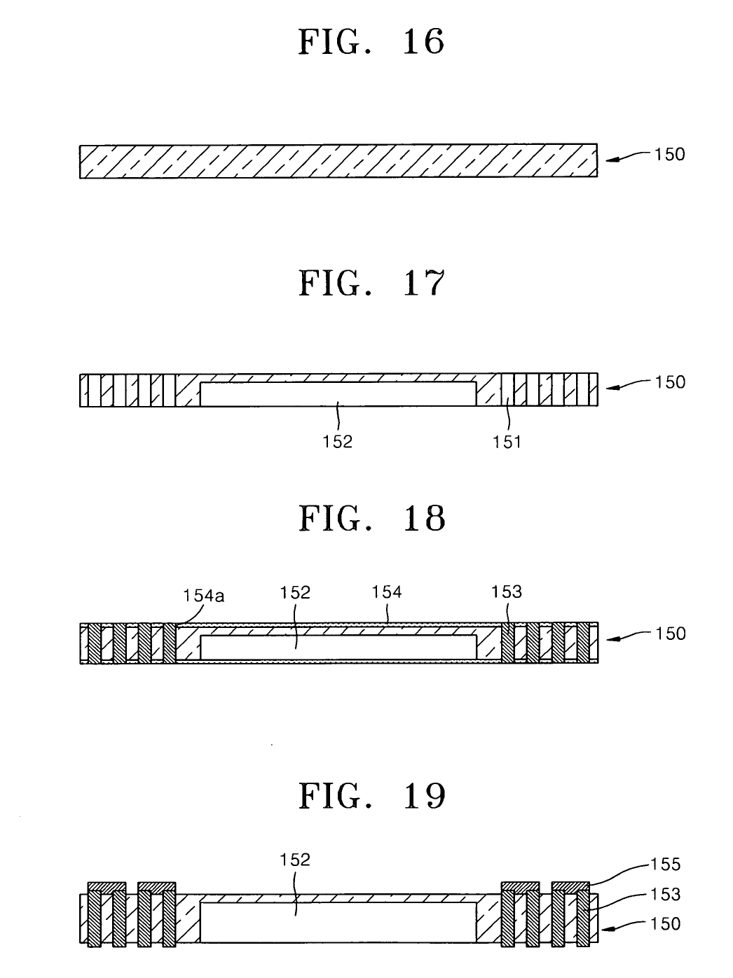

FIG. 16 is a cross-sectional view for explaining an operation of preparing a second substrate 150 in a method of manufacturing a circuit board, according to another embodiment of the present invention. FIG. 17 is a cross-sectional view for explaining an operation of forming through holes 151 in the second substrate 150 illustrated in FIG. 16, according to another embodiment of the present invention. FIG. 18 is a cross-sectional view for explaining an operation of forming a connection portion 153 comprising a conductive material in the through holes 151 of the second substrate 150 illustrated in FIG. 17, according to another embodiment of the present invention. FIG. 19 is a cross-sectional view for explaining an operation of forming a second pattern portion 155 on the second substrate 150 illustrated in FIG. 18, according to another embodiment of the present invention.

In the present embodiment, operations for preparing the first substrate 10 may be the same as those illustrated in FIGS. 1 through 3.

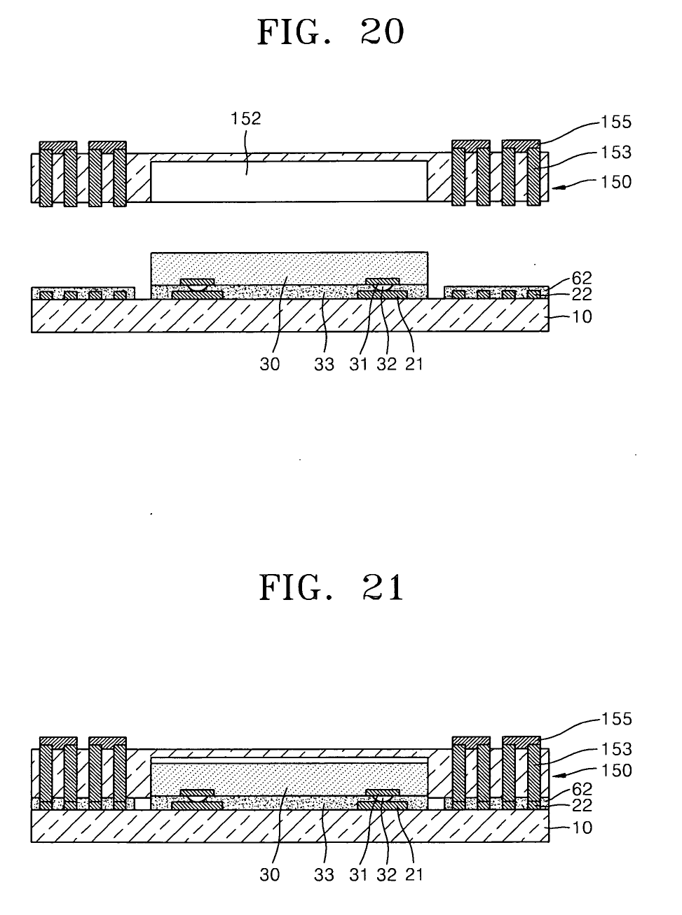

In operations illustrated in FIGS. 1 through 13, the second substrate 40 having the approximately same thickness as that of the semiconductor chip 30 is disposed between the first substrate 10 and the third substrate 50. On the other hand, in the present embodiment a circuit board is embodied as a two-layered structure having no intermediate substrate. In one case of the present embodiment, the second and third substrates 40, 50 may be unitary or integral with each other to define a single substrate 150 that is used to embed the chip 30 installed on the first substrate 10 (see, for example, FIGS. 20 and 21).

Turning now to FIGS. 16-19, the single substrate that couples with the first substrate for embedding the chip is described. The second substrate 150 is formed of an insulating material. The second substrate 150 includes the through holes 151, a housing portion 152 for housing a part of an upper surface of the semiconductor chip 30 (FIG. 3), and the second pattern portion 155 formed on the second substrate 150. When the circuit board is a flexible circuit board, the second substrate 150 may be formed of a flexible material, such as a polyimide resin, or the like.

The preparing of the second substrate 150 includes: forming the through holes 151 in the third substrate 150; and forming the connection portion 153 comprising a conductive material in the through holes 151.

The through holes 151 function as via holes that electrically connect a first pattern portion 22 of the first substrate 10 to the second pattern portion 155 formed on the second substrate 150 (see FIGS. 19, 20 and 21). Thus, the through holes 151 are formed in a portion of the second substrate 150 which corresponds to or is generally aligned with a part of the first pattern portion 22 of the first substrate 10.

The housing portion 152 is concavely formed in the second substrate 150 in a shape corresponding to a perimeter and height/thickness of the semiconductor chip 30. When the second substrate 150 is coupled to the first substrate 10 (as is best illustrated in FIG. 21), the housing portion 152 of the second substrate 150 surrounds and supports the semiconductor chip 30. Thus the housing portion 152 can insulate the semiconductor chip 30 from other elements of the circuit board. To achieve this, the housing portion 152 of the second substrate 150 may have a thickness that is the approximately same as the thickness of the semiconductor chip 30. In some instances, a portion of the substrate 150 may be carved out or otherwise removed to form a recess, depression or cavity defining the housing portion 152.

The connection portion 153 comprising a conductive material may be formed in the through holes 151 by using electroless plating. A passivation layer 154 (e.g., a mask), in which openings 154a corresponding to the through holes 151 are formed, is attached onto the second substrate 150 illustrated in FIG. 17, and then electroless plating is performed with respect to the resulting structure. Thus, the connection portion 153 is formed in the through holes 151, as illustrated in FIG. 18. Since the connection portion 153 should be conductive, the connection portion 153 may comprise a conductive material such as copper (Cu).

The connection portion 153 is formed using the electroless plating, but the present invention is not limited thereto. The connection portion 153 should electrically connect circuit patterns between the first substrate 10 and the second substrate 150, and thus the connection portion 153 may be formed using various additive or subtractive methods known in the art such as deposition, and a method of filling the through holes 151 with conductive powder and hardening the conductive powder.

FIG. 20 is a cross-sectional view of an operation of coupling the first substrate 10 to the second substrate 150 illustrated in FIG. 19, according to another embodiment of the present invention. FIG. 21 is a cross-sectional view of a completed circuit board, according to another embodiment of the present invention.

The first and second substrates 10 and 150 are each prepared, and then the first substrate 10 and the second substrate 150 are coupled to each other, as illustrated in FIG. 20. In the coupling operation, the first substrate 10 and the second substrate 150 are disposed so as to align the first pattern portion 22 of the first substrate 10, and the connection portion 153 of the second substrate 150 with each other, and then the first and second substrates 10 and 150 are coupled to each other by using conductive adhesive or adhesives. The conductive adhesive or adhesives between the first substrate 10 and the second substrate 150 may include an anisotropic conductive material (e.g., ACF).

An ACF 62 is coated on the first pattern portion 22 between the first substrate 10 and the second substrate 150. Thus, after a subsequent hardening or curing operation is performed, the first pattern portion 22 and the connection portion 153 are electrically connected to each other due to the ACF 62. Furthermore, the first substrate 10 and the second substrate 150 are mechanically coupled or fastened to each other as well.

After the coupling operation, an operation of hardening or curing the ACF 62 may be performed. The hardening or curing operation may be performed using a method in which heat and pressure or heat and sonic waves are applied to the first and second substrates 10 and 150. When heat is applied together with sonic waves, the first pattern portion 22 and the connection portion 153 are electrically connected to each other due to the ACF 62.

As described previously, the circuit board including the semiconductor chip 30 (e.g., an electronic chip) embedded therein is completed, as illustrated in FIG. 21. Since non-solder bumps 32 attached to connection terminals 31 of the semiconductor chip 30 are electrically connected to a terminal 21 of the first substrate 10 due to an ACF 33, the semiconductor chip 30 is electrically connected to the first substrate 10 and embedded in the circuit board.

When the first and second substrates 10 and 150 are each formed of a flexible material, such as a polyimide resin, the circuit board is a flexible circuit board.

In a method of manufacturing a circuit board according to the present invention, since the circuit board can be manufactured using a simple operation of coupling substrates, which are previously prepared, by an ACF, an additional drill operation or etching operation is not required. Thus, the method can be simplified, and thus manufacturing costs of the method can be reduced.

According to the present invention, since a semiconductor chip is embedded in a circuit by using flip chip mounting technique with an ACF, and circuit patterns of layers can be electrically connected to each other by the ACF, danger of damaging the semiconductor chip can be reduced in comparison with a conventional method in which a drill operation is used.

According to the present invention, since the substrates are coupled to each other by interposing therebetween an ACF, and simultaneously, circuit patterns of the substrates are electrically connected by the ACF, it is easy to manufacture the circuit board including a circuit pattern having a fine pitch.

According to the present invention, since the first, second, and third substrates are formed of a flexible material, such as a polyimide resin, a circuit board having good flexibility can be manufactured.

In the present invention, when the first, second, and the third substrates are each formed of a flexible material in order to manufacture a flexible circuit board, the first, second, and third substrates are prepared to be wound around a roll, the first, second, and third substrates are released from the roll, and various operations for manufacturing the circuit board can be simultaneously performed.

According to the present invention, in an electronic chip embedded circuit board and a method of manufacturing the circuit board, since respective operations of preparing first, second, and third substrates can be simultaneously performed, the time of manufacturing the circuit board can be reduced, in comparison with a conventional manufacturing method in which a circuit board is manufactured by sequentially forming and subsequently stacking various substrates.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A method of manufacturing a device-embedded circuit board, the method comprising:
forming a first pattern portion on a first insulating substrate;
coupling an active or passive device to the first substrate for electrical connection with the first pattern portion;
forming a first conductive path through a second insulating substrate;
forming in the second insulating substrate a housing portion having a shape complementary to a perimeter of the active or passive device;
forming a second conductive path through a third insulating substrate;
applying conductive adhesive to one or more portions of the first, second and third insulating substrates;
aligning the first pattern portion, the first conductive path and the second conductive path;
compressing together the first, second and third insulating substrates to electrically connect the first pattern portion, the first conductive path and the second conductive path; and
curing the conductive adhesive.

2. The method of claim 1, wherein the conductive adhesive comprises an anisotropic conductive material.

3. The method of claim 2, wherein the anisotropic conductive material is an anisotropic conductive film (ACF).

4. The method of claim 1 further comprising forming a second pattern portion on an external surface of the third insulating substrate, the second pattern portion being in electrical connection with the second conductive path.

5. The method of claim 1, wherein the curing step comprises applying heat and pressure to the first, second, and third insulating substrates.

6. The method of claim 1, wherein the curing step comprises applying sonic waves and pressure to the first, second, and third insulating substrates.

7. The method of claim 1, wherein the step of forming a first pattern portion on a first insulating substrate comprises:
applying a conductive material to the first insulating substrate;
coating resist on the conductive material;
exposing and developing the resist; and
removing a part of the conductive material.

8. The method of claim 7 wherein the removing step comprises etching.

9. The method of claim 1, wherein the step of forming a first conductive path through a second insulating substrate comprises:
forming at least one via hole through the second insulating substrate;
plating the at least one via hole to define the first conductive path.

10. A method of manufacturing a device-embedded circuit board, the method comprising:
coupling an active or passive device to a first insulating substrate;
forming a housing portion in a second insulating substrate relative to a perimeter and a thickness of the active or passive device;
forming a conductive path through the second insulating substrate relative to the housing portion and a circuit pattern on the first insulating substrate; and
coupling the first and second insulating substrates so that the housing portion surrounds the active or passive device, and the conductive path is in electrical communication with the circuit pattern on the first insulating substrate.

11. The method of claim 10 wherein the coupling step comprises:
applying conductive adhesive to at least one of the first and second insulating substrates;
aligning the circuit pattern and the conductive path; and
curing the conductive adhesive.

12. The method of claim 11 wherein the applying step comprises disposing conductive adhesive on at least one of the circuit pattern and the conductive path

13. The method of claim 10, wherein the conductive adhesive is an anisotropic conductive film (ACF).

14. The method of claim 10 further comprising forming a second circuit pattern on an external surface of the second insulating substrate, the second circuit pattern being in electrical connection with the conductive path.

15. The method of claim 10 wherein the step of coupling an active or passive device to a first insulating substrate comprises:
applying a conductive material to the first insulating substrate;
coating resist on the conductive material;
exposing and developing the resist;
removing a part of the conductive material to define the circuit pattern; and
electrically connecting the active or passive device to the circuit pattern.

16. A device-embedded circuit board comprising:
a first substrate including a surface bearing a circuit pattern;
an active or passive device on the surface of the first substrate and electrically connected to the circuit pattern;
a second substrate including a conductive path through the second substrate, and a housing portion for protecting the active or passive device; and
a coupling that electrically connects the circuit pattern with the conductive path and that bonds the first and second substrates together.

17. The device-embedded circuit board of claim 16 wherein the housing portion comprises a generally concave recess.

18. The device-embedded circuit board of claim 16 wherein the second substrate comprises:
a first portion including a first aperture and a second aperture, the first aperture defining the housing portion and having a shape complementary to a perimeter of the active of passive device, and the second aperture having a first conductive member defining a first portion of the conductive path; and
a second portion including a third aperture generally aligned with the second aperture and having a second conductive member defining a second portion of the conductive path.

19. The device-embedded circuit board of claim 16 wherein the coupling comprises an anisotropic conductive film (ACF) disposed on at least one of the circuit pattern and the conductive path.

20. The circuit board of claim 16 wherein the first and second substrates are flexible.
